(19) United States
(12) Patent Application Publication
(10) Pub. No.: US 2024/0304618 A1
(43) Pub. Date: Sep. 12, 2024

(54) ELECTRONIC DEVICE

(71) Applicant: Hexawave, Inc., Hsinchu (TW)

(72) Inventors: Yung-Pin LIU, Hsinchu (TW); Ming-Yan TSAI, Hsinchu (TW)

(21) Appl. No.: 18/594,458

(22) Filed: Mar. 4, 2024

Related U.S. Application Data
(60) Provisional application No. 63/488,538, filed on Mar. 6, 2023.

(30) Foreign Application Priority Data
Sep. 15, 2023 (TW) 112135228

(51) Int. Cl. H01L 27/088; H01L 27/06

(52) U.S. Cl. CPC H01L 27/0883; H01L 27/0617

(57) ABSTRACT

An electronic device includes a switch element and a voltage clamping element. The switch element includes a first end, a second end, and a control end. The switch element conducts the first end with the second end of the switch element according to a first voltage on the control end. The voltage clamping element includes a first end, a second end, and a control end. The control end of the voltage clamping element is electrically connected to the second end of the switch element and a ground voltage, and the second end of the voltage clamping element is electrically connected to the control end of the switch element. The voltage clamping element clamps the first voltage to a preset voltage based on the voltage difference between the first voltage and the ground voltage.

### CROSS REFERENCE TO RELATED APPLICATIONS

This application claims priority of U.S. Provisional Application No. 63/488,538, filed on Mar. 6, 2023, and Taiwan Patent Application No. 112135228, filed on Sep. 15, 2023, the entirety of which is incorporated by reference herein.

### FIELD OF THE INVENTION

The present invention relates to an electronic device, and, in particular, to an electronic device with a gate protection function.

### DESCRIPTION OF THE RELATED ART

Switch elements made of silicon (Si), silicon carbide (SiC), gallium nitride (GaN), etc. include three terminals: a gate, a drain, and a source. The switch element uses the gate to apply voltage to induce electrons to gather under the gate to form a channel, allowing the electrons to pass from the source through the channel to the drain to form a current.

The gate functions as a switch to control the channel, which is the key to the switch element. Therefore, if the gate is subjected to excessive voltage and breaks down, the switch element will lose its switching ability, which is equivalent to destruction. Therefore, gate voltage control is an important issue.

### BRIEF SUMMARY OF THE INVENTION

In order to solve the above problems, an embodiment of the present invention provides an electronic device. The switch element includes a first end, a second end, and a control end. The switch element conducts the first end with the second end of the switch element according to a first voltage on the control end. The voltage clamping element includes a first end, a second end, and a control end. The control end of the voltage clamping element is electrically connected to the second end of the switch element and a ground voltage, and the second end of the voltage clamping element is electrically connected to the control end of the switch element. The voltage clamping element clamps the first voltage to a preset voltage based on the voltage difference between the first voltage and the ground voltage.

According to the electronic device described above, the switch element includes a first transistor. The voltage clamping element includes a second transistor. The first transistor has a first threshold voltage. The second transistor has a second threshold voltage. The first threshold voltage is higher than 0. The second threshold voltage is lower than 0.

According to the electronic device described above, the preset voltage is equal to the absolute value of the second threshold voltage of the second transistor.

According to the electronic device described above, the first end of the voltage clamping element receives an input voltage.

According to the electronic device described above, when the voltage difference between the first voltage and the ground voltage is lower than the absolute value of the second threshold voltage of the second transistor, the first voltage is equal to the input voltage.

According to the electronic device described above, when the voltage difference between the first voltage and the ground voltage is higher than or equal to the absolute value of the second threshold voltage of the second transistor, the first voltage is equal to the absolute value of the second threshold voltage.

The electronic device further includes a clamped driving element. The clamped driving element includes a first end, a second end, and a control end. The clamped driving element conducts the first end with the second end of the clamped driving element according to the first voltage, so that the control end of the voltage clamping element is electrically connected to the ground voltage.

According to the electronic device described above, the clamped driving element includes a third transistor, the third transistor has a third threshold voltage, and the third threshold voltage is higher than 0.

According to the electronic device described above, the first end of the clamped driving element is electrically connected to the control end of the voltage clamping element. The control end of the clamped driving element is electrically connected to the second end of the voltage clamping element. The second end of the clamped driving element is electrically connected to the ground voltage.

According to the electronic device described above, when the voltage difference between the first voltage and the ground voltage is lower than the third threshold voltage, the clamped driving element does not conduct the first end with the second end of the clamped driving element.

According to the electronic device described above, when the voltage difference between the first voltage and the ground voltage is higher than or equal to the third threshold voltage, the clamped driving element conducts the first end with the second end of the clamped driving element, so that the control end of the voltage clamping element is electrically connected to the ground voltage.

According to the electronic device described above, the first end of the switch element is electrically connected to a second voltage.

According to the electronic device described above, the first transistor is an enhancement mode field-effect transistor (FET), and the second transistor is a depletion mode FET.

According to the electronic device described above, the third transistor is an enhancement mode FET.

### BRIEF DESCRIPTION OF THE DRAWINGS

The present invention can be more fully understood by reading the subsequent detailed description and examples with references made to the accompanying drawings, wherein:

FIG. 1 is a schematic diagram of an electronic device 100 in accordance with some embodiments of the present invention.

FIG. 2 is a detail schematic diagram of the electronic device 100 in FIG. 1 in accordance with some embodiments of the present invention.

FIG. 3 is a schematic diagram of an electronic device 300 in accordance with some embodiments of the present invention.

FIG. 4 is a detail schematic diagram of the electronic device 300 in FIG. 3 in accordance with some embodiments of the present invention.

FIG. 5 is a voltage versus time diagram of a first voltage V and an input voltage V_{B} of the electronic device 100 in FIG. 1 in accordance with some embodiments of the present invention.

### DETAILED DESCRIPTION OF THE INVENTION

In order to make the above purposes, features, and advantages of some embodiments of the present invention more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” and/or “include” used in the present invention are used to indicate the existence of specific technical features, values, method steps, operations, units and/or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present invention. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, “third”, “fourth”, “fifth”, and “sixth” are used to describe components. They are not used to indicate the priority order of or advance relationship, but only to distinguish components with the same name.

It should be noted that the technical features in different embodiments described in the following can be replaced, recombined, or mixed with one another to constitute another embodiment without departing from the spirit of the present invention.

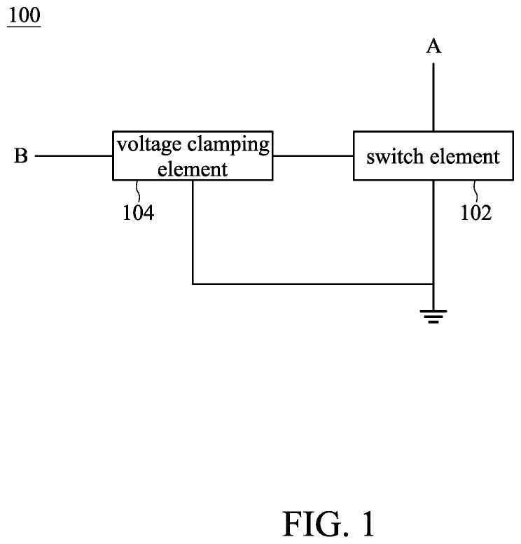

FIG. 1 is a schematic diagram of an electronic device 100 in accordance with some embodiments of the present invention. As shown in FIG. 1, the electronic device 100 includes a switch element 102 and a voltage clamping element 104. In some embodiments, the switch element 102 includes a first end, a second end, and a control end. The switch element 102 conducts the first end with the second end of the switch element 102 according to a first voltage on its control end. In some embodiments, the first end of the switch element 102 is electrically connected to a node A, and the second end of the switch element 102 is electrically connected to a ground end. In some embodiments, the voltage clamping element 104 includes a first end, a second end, and a control end. The control end of the voltage clamping element 104 is electrically connected to the second end of the switch element 102 and the ground end. The first end of the voltage clamping element 104 is electrically connected to a node B. The second end of the voltage clamping element 104 is electrically connected to the control end of the switch element 102. In some embodiments, an input voltage is applied to the node B. A ground voltage is applied to the ground end. A second voltage is applied to the node A. In some embodiments, the second end of the voltage clamping element 104 has a first voltage. The voltage clamping element 104 clamps the first voltage to a preset voltage according to the voltage difference between the first voltage and the ground voltage. In some embodiments, the switch element 102 serves as an amplifier, and the voltage clamping element 104 is used to protect the control end of the switch element 102.

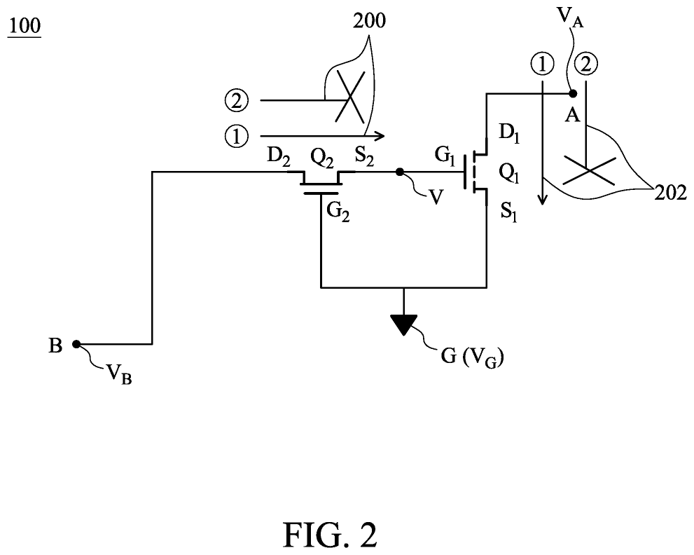

FIG. 2 is a detail schematic diagram of the electronic device 100 in FIG. 1 in accordance with some embodiments of the present invention. As shown in FIG. 2, the switch element 102 includes a first transistor Q₁. The first transistor Q₁ includes a gate G₁, a source S₁, and a drain D₁. Comparing FIG. 1 and FIG. 2, the first end of the switch element 102 is the drain D₁ of the first transistor Q₁. The second end of the switch element 102 is the source S₁ of the first transistor Q₁. The control end of the switch element 102 is the gate G₁ of the first transistor Q₁. As shown in FIG. 2, the voltage clamping element 104 includes a second transistor Q₂. The second transistor Q₂ includes a gate G₂, a source S₂, and a drain D₂. Comparing FIG. 1 and FIG. 2, the first end of the voltage clamping element 104 is the drain D₂ of the second transistor Q₂. The second end of the voltage clamping element 104 is the source S₂ of the second transistor Q₂. The control end of the voltage clamping element 104 is the gate G₂ of the second transistor Q₂.

In some embodiments, the first transistor Q₁ has a first threshold voltage V_{TH,Q1}. The second transistor Q₂ has a second threshold voltage V_{TH,Q2}. In some embodiments, the first threshold voltage V_{TH,Q1} is higher than 0, and the second threshold voltage V_{TH,Q2} is lower than 0. In other words, the first transistor Q₁ is a normal off transistor. The second transistor Q₂ is a normal on transistor. In some embodiments, when the gate voltage is not applied to the normal off transistor, the normal off transistor is in an off state, and sufficient positive voltage must be applied to the normal off transistor to turn on the normal off transistor. The aforementioned sufficient positive voltage is called a threshold voltage. In contrast, sufficient negative voltage must be applied to the normal on transistor to turn off the normal on transistor.

In some embodiments of FIG. 2, the drain D₁ of the first transistor Q₁ is electrically connected to the node A. The node A has a second voltage V_{A}. The source S₁ of the first transistor Q₁ is electrically connected to a ground end G. The ground end G has a ground voltage V_{G}. The gate G₁ of the first transistor Q₁ is electrically connected to the source S₂ of the second transistor Q₂. The gate G₁ of the first transistor Q₁ has a first voltage V. The drain D₂ of the second transistor Q₂ is electrically connected to the node B. The node B has an input voltage V_{B}. The gate G₂ of the second transistor Q₂ is electrically connected to the ground end G. In some embodiments, the first transistor Q₁ is an enhancement mode field-effect transistor (FET), and the second transistor Q₂ is a depletion mode FET, but the present invention is not limited thereto. In some embodiments, the second transistor Q₂ clamps the first voltage V at the preset voltage according to the voltage difference between the first voltage V and the ground voltage V_{G}. In some embodiments, the preset voltage is equal to the absolute value of the second threshold voltage V_{TH,Q2} of the second transistor Q₂, for example, expressed as |VTH,Q2|.

In some embodiments, when the voltage difference between the first voltage V and the ground voltage V_{G} is lower than the absolute value of the second threshold voltage |V_{TH,Q2}| of the second transistor Q₂, the first voltage V is equal to the input voltage V_{B}. In some embodiments, when the voltage difference between the first voltage V and the ground voltage V_{G} is lower than the absolute value of the second threshold voltage |V_{TH,Q2}| of the second transistor Q₂, or which is called a state (1), a current 200 flows from the node B to the drain D₂ of the second transistor Q₂, passes through the second transistor Q₂, and flows out from the source S₂ of the second transistor Q₂ to the gate G₁ of the first transistor Q₁. In some embodiments, when in the state (1), a current 202 flows from the node A to the drain D₁ of the first transistor Q₁, passes through the first transistor Q₁, and flows out from the source S₁ of the first transistor Q₁ to the ground end G.

In some embodiments, when the voltage difference between the first voltage V and the ground voltage V_{G} is higher than or equal to the absolute value of the second threshold voltage |V_{TH,Q2}| of the second transistor Q₂, the first voltage V is equal to the absolute value of the second threshold voltage |V_{TH,Q2}|. In some embodiments, when the voltage difference between the first voltage V and the ground voltage V_{G} is higher than or equal to the absolute value of the second threshold voltage |V_{TH,Q2}| of the second transistor Q₂, or which is called a state (2), there is no current 200 and current 202.

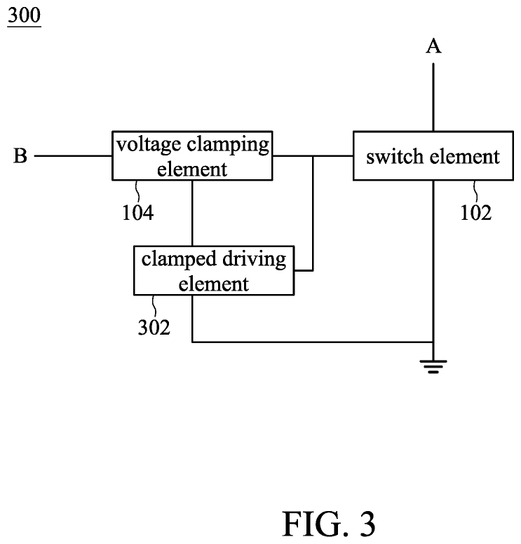

FIG. 3 is a schematic diagram of an electronic device 300 in accordance with some embodiments of the present invention. As shown in FIG. 3, the electronic device 300 includes the switch element 102, the voltage clamping element 104, and a clamped driving element 302. In some embodiments, the switch element 102 includes a first end, a second end, and a control end. The switch element 102 conducts the first end with the second end of the switch element 102 according to a first voltage at its control end. In some embodiments, the first end of the switch element 102 is electrically connected to the node A, and the second end of the switch element 102 is electrically connected to the ground end. In some embodiments, the voltage clamping element 104 includes a first end, a second end, and a control end. The clamped driving element 302 includes a first end, a second end, and a control end. The control end of the voltage clamping element 104 is electrically connected to the first end of the clamped driving component 302. The first end of the voltage clamping element 104 is electrically connected to the node B. The second end of the voltage clamping element 104 is electrically connected to the control end of the switch element 102 and the control end of the clamped driving element 302. The second end of the clamped driving element 302 is electrically connected to the second end of the switch element 102 and the ground end. In some embodiments, the input voltage is applied to the node B. The ground voltage is applied to the ground end. The second voltage is applied to the node A.

In some embodiments, the clamped driving element 302 conducts the first end with the second end of the clamped driving element 302 according to the first voltage V, so that the control end of the voltage clamping element 104 is electrically connected to the ground voltage.

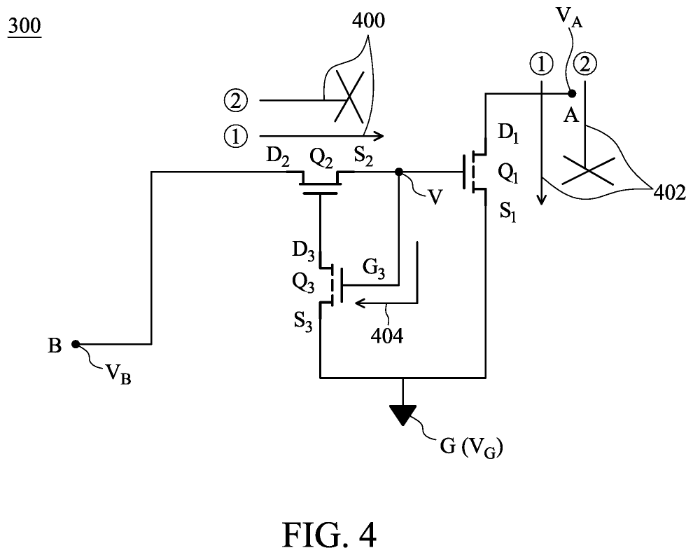

FIG. 4 is a detail schematic diagram of the electronic device 300 in FIG. 3 in accordance with some embodiments of the present invention. As shown in FIG. 4, the switch element 102 includes a first transistor Q₁. The first transistor Q₁ includes a gate G₁, a source S₁, and a drain D₁. Comparing FIG. 3 and FIG. 4, the first end of the switch element 102 is the drain D₁ of the first transistor Q₁. The second end of the switch element 102 is the source S₁ of the first transistor Q₁. The control end of the switch element 102 is the gate G₁ of the first transistor Q₁. As shown in FIG. 4, the voltage clamping element 104 includes a second transistor Q₂. The second transistor Q₂ includes a gate G₂, a source S₂, and a drain D₂. Comparing FIG. 3 and FIG. 4, the first end of the voltage clamping element 104 is the drain D₂ of the second transistor Q₂. The second end of the voltage clamping element 104 is the source S₂ of the second transistor Q₂. The control end of the voltage clamping element 104 is the gate G₂ of the second transistor Q₂. As shown in FIG. 4, the clamped driving element 302 includes a third transistor Q₃. The third transistor Q₃ includes a gate G₃, a source S₃, and a drain D₃. Comparing FIG. 3 and FIG. 4, the first end of the clamped driving element 302 is the drain D₃ of the third transistor Q₃. The second end of the clamped driving element 302 is the source S₃ of the third transistor Q₃. The control end of the clamped driving element 302 is the gate G₃ of the third transistor Q₃.

In some embodiments, the third transistor Q₃ has a third threshold voltage V_{TH,Q3}. The third threshold voltage V_{TH,Q3} is higher than 0. In some embodiments, the third transistor Q₃ is a normal off transistor. In some embodiments, the third transistor Q₃ is an enhancement mode FET, but the present invention is not limited thereto.

In some embodiments of FIG. 4, the drain D₁ of the first transistor Q₁ is electrically connected to the node A. The node A has a second voltage V_{A}. The source S₁ of the first transistor Q₁ is electrically connected to the ground end G. The ground end G has a ground voltage V_{G}. The gate G₁ of the first transistor Q₁ is electrically connected to the source S₂ of the second transistor Q₂ and the gate G₃ of the third transistor Q₃. The gate G₁ of the first transistor Q₁ has a first voltage V. The drain D₂ of the second transistor Q₂ is electrically connected to the node B. The node B has an input voltage V_{B}. The gate G₂ of the second transistor Q₂ is electrically connected to the drain D₃ of the third transistor Q₃. The source S₃ of the third transistor Q₃ is electrically connected to the ground end G.

In some embodiments, when the voltage difference between the first voltage V and the ground voltage V_{G} is lower than the third threshold voltage V_{TH, Q3}, the clamped driving element 302 does not conduct the drain D₃ with the source S₃ of the third transistor Q₃. In some embodiments, when the voltage difference between the first voltage V and the ground voltage V_{G} is higher than or equal to the third threshold voltage V_{TH,Q3}, the clamped driving element 302 turns on the drain D₃ and the source S₃ of the third transistor Q₃, so that the gate G₂ of the second transistor Q₂ is electrically connected to the ground voltage V_{G}. When the voltage difference between the first voltage V and the ground voltage V_{G} is higher than or equal to the third threshold voltage V_{TH,Q3}, and the voltage difference between the first voltage V and the ground voltage V_{G} is lower than the absolute value of the second threshold voltage |V_{TH,Q2}| of the second transistor Q₂, or which is called a state (1), a current 400 flows from the node B into the drain D₂ of the second transistor Q₂, passes through the second transistor Q₂, and flows out from the source S₂ of the second transistor Q₂ to the gate G₁ of the first transistor Q₁. In some embodiments, when in the state (1), a current 402 flows from the node A to the drain D₁ of the first transistor Q₁, passes through the first transistor Q₁, and flows out from the source S₁ of the first transistor Q₁ to the ground end G. When in the state (1), a current 404 flows from the gate G₁ of the first transistor Q₁ to the gate G₃ of the third transistor Q₃, so that the third transistor Q₃ is turned on.

In some embodiments, when the voltage difference between the first voltage V and the ground voltage V_{G} is higher than or equal to the third threshold voltage V_{TH,Q3}, and the voltage difference between the first voltage V and the ground voltage V_{G} is higher than or equal to the absolute value of the second threshold voltage |V_{TH,Q2}| of the second transistor Q₂, or which is called a state (2), a current 404 flows from the gate G₁ of the first transistor Q₁ to the gate G₃ of the third transistor Q₃, so that the third transistor Q₃ is turned on, but there is no current 400 or 402.

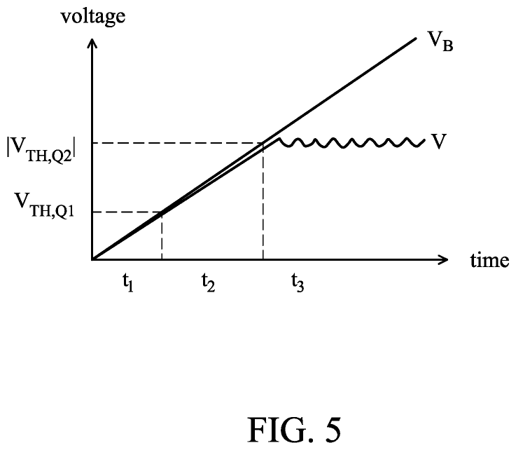

FIG. 5 is a voltage versus time diagram of a first voltage V and an input voltage V_{B} of the electronic device 100 in FIG. 1 in accordance with some embodiments of the present invention. Please referrer to FIG. 2 and FIG. 5. During a period t₁, the second transistor Q₂ is turned on. Both the first voltage V and the input voltage V_{B} are lower than the first threshold voltage V_{TH,Q1} of the first transistor Q₁, and the first voltage V rises as the input voltage V_{B} rises. The first voltage V is equal to the input voltage V_{B}. During the period t₁, since the first voltage V is still lower than the first threshold voltage V_{TH,Q1} of the first transistor Q₁, the first transistor Q₁ is still turned off. During a period t₂, the second transistor Q₂ is turned on. Both the first voltage V and the input voltage V_{B} are higher than or equal to the first threshold voltage V_{TH,Q1} of the first transistor Q₁, but both are lower than the absolute value of the second threshold voltage |V_{TH,Q2}| of the second transistor Q₂, and the first voltage V rises as the input voltage V_{B} rises. The first voltage V is equal to the input voltage V_{B}.

During a period t3, when both the first voltage V and the input voltage V_{B} are slightly higher than the absolute value of the second threshold voltage |V_{TH,Q2}| of the second transistor Q₂, the second transistor Q₂ is not yet completely turned off. Affected by this, the ability of the input voltage V_{B} to affect the first voltage V decreases, so that the first voltage V will be slightly lower than the input voltage V_{B}. However, as the input voltage V_{B} rises, the second transistor Q₂ becomes to turn off, and the input voltage V_{B} no longer drives the first voltage V to rise, so that the first voltage V begins to fall. When the first voltage V drops to the absolute value of the second threshold voltage |V_{TH,Q2}|, the voltage difference between the gate G₂ and the source S₂ of the second transistor Q₂ is still slightly higher than the second threshold voltage V_{TH,Q2}, and the second transistor Q₂ is slightly turned on, so that the input voltage V_{B} re-controls the first voltage V, and the above cycle is repeated. Therefore, no matter how much voltage value the input voltage V_{B} rises to, the first voltage V will be clamped at the absolute value of the second threshold voltage |V_{TH,Q2}| of the second transistor Q₂.

Similarly, please refer to FIG. 4 and FIG. 5 at the same time. After the third transistor Q₃ is turned on, the voltage of the gate G₂ of the second transistor Q₂ is 0V, thus creating a voltage difference with the source S₂ of the second transistor Q₂. Only then can the second transistor Q₂ be turned off and clamp the first voltage V. In other words, only when the third transistor Q₃ is turned on, the second transistor Q₂ has a clamping function. Before the third transistor Q₃ is turned on, the second transistor Q₂ has no switching capability, so that the first voltage V is equal to the input voltage V_{B}. In summary, when the input voltage V_{B} is lower than the absolute value of the second threshold voltage |V_{TH,Q2}| of the second transistor Q₂, the first voltage V is equal to the input voltage V_{B}. When the input voltage V_{B} is higher than or equal to the absolute value of the second threshold voltage |V_{TH,Q2}| of the second transistor Q₂, the second transistor Q₂ will clamp the first voltage V to protect the first transistor Q₁ (i.e., the main switch element) from being damaged by excessive voltage, thereby protecting the gate G₁ of the first transistor Q₁.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a switch element, comprising a first end, a second end, and a control end, configured to conduct the first end with the second end of the switch element according to a first voltage on the control end; and
a voltage clamping element, comprising a first end, a second end, and a control end; wherein the control end of the voltage clamping element is electrically connected to the second end of the switch element and a ground voltage, and the second end of the voltage clamping element is electrically connected to the control end of the switch element,
wherein the voltage clamping element clamps the first voltage to a preset voltage based on a voltage difference between the first voltage and the ground voltage.

2. The electronic device as claimed in claim 1, wherein the switch element comprises a first transistor, and the voltage clamping element comprises a second transistor; wherein the first transistor has a first threshold voltage, the second transistor has a second threshold voltage, the first threshold voltage is higher than 0, and the second threshold voltage is lower than 0.

3. The electronic device as claimed in claim 2, wherein the preset voltage is equal to an absolute value of the second threshold voltage of the second transistor.

4. The electronic device as claimed in claim 2, wherein the first end of the voltage clamping element receives an input voltage.

5. The electronic device as claimed in claim 4, wherein when the voltage difference between the first voltage and the ground voltage is lower than the absolute value of the second threshold voltage of the second transistor, the first voltage is equal to the input voltage.

6. The electronic device as claimed in claim 4, wherein when the voltage difference between the first voltage and the ground voltage is higher than or equal to the absolute value of the second threshold voltage of the second transistor, the first voltage is equal to the absolute value of the second threshold voltage.

7. The electronic device as claimed in claim 1, further comprising:
a clamped driving element, comprising a first end, a second end, and a control end, configured to conduct the first end with the second end of the clamped driving element according to the first voltage, so that the control end of the voltage clamping element is electrically connected to the ground voltage.

8. The electronic device as claimed in claim 7, wherein the clamped driving element comprises a third transistor, the third transistor has a third threshold voltage, and the third threshold voltage is higher than 0.

9. The electronic device as claimed in claim 7, wherein the first end of the clamped driving element is electrically connected to the control end of the voltage clamping element, the control end of the clamped driving element is electrically connected to the second end of the voltage clamping element, and the second end of the clamped driving element is electrically connected to the ground voltage.

10. The electronic device as claimed in claim 8, wherein when the voltage difference between the first voltage and the ground voltage is lower than the third threshold voltage, the clamped driving element does not conduct the first end with the second end of the clamped driving element.

11. The electronic device as claimed in claim 8, wherein when the voltage difference between the first voltage and the ground voltage is higher than or equal to the third threshold voltage, the clamped driving element conducts the first end with the second end of the clamped driving element, so that the control end of the voltage clamping element is electrically connected to the ground voltage.

12. The electronic device as claimed in claim 1, wherein the first end of the switch element is electrically connected to a second voltage.

13. The electronic device as claimed in claim 2, wherein the first transistor is an enhancement mode field-effect transistor (FET), and the second transistor is a depletion mode FET.

14. The electronic device as claimed in claim 8, wherein the third transistor is an enhancement mode FET.
